(19) United States
(12) Patent Application Publication
(10) Pub. No.: US 2010/0144161 A1
(43) Pub. Date: Jun. 10, 2010

(54) SEMICONDUCTOR DEVICE MANUFACTURING METHOD AND SUBSTRATE PROCESSING APPARATUS

(75) Inventor: Iwao NAKAMURA, Imiza-shi (JP)

Correspondence Address: BRUNDIDGE & STANGER, P.C., 2318 MILL ROAD, SUITE 1020, ALEXANDRIA, VA, 22314, US

(73) Assignee: HITACHI-KOKUSAI ELECTRIC INC., Tokyo (JP)

(21) Appl. No.: 12/632,316

(22) Filed: Dec. 7, 2009

(30) Foreign Application Priority Data
Dec. 9, 2008 (JP) 2008-313164

(51) Int. Cl. H01L 21/316

(52) U.S. Cl. 438/767; 118/666; 257/E21.285

(57) ABSTRACT

A semiconductor device manufacturing method and a substrate processing apparatus are provided to reduce contaminants generating due to striping of an oxide film formed on a silicon carbide member. The manufacturing method includes: loading a substrate into a silicon carbide reaction tube; forming an oxide film on the substrate by supplying oxidizing gas into the reaction tube and causing thermal oxidation; unloading the processed substrate from the reaction tube; and in a state where the processed substrate is unloaded from the reaction tube, after increasing an inside temperature of the reaction tube until temperature of an oxide film formed on an inner wall of the reaction tube through the thermal oxidation is increased to at least a temperature corresponding to a strain point of the oxide film, decreasing the inside temperature of the reaction tube to below a temperature at which the processed substrate is unloaded from the reaction tube.

### CROSS-REFERENCE TO RELATED PATENT APPLICATION

This U.S. non-provisional patent application claims priority under 35 U.S.C. §119 of Japanese Patent Application No. 2008-313164, filed on Dec. 9, 2008, in the Japanese Patent Office, the entire contents of which are hereby incorporated by reference.

### BACKGROUND OF THE INVENTION

1. Field of the Invention

The present invention relates to a semiconductor device manufacturing method including a process of oxidizing a wafer by using a member made of silicon carbide, and a substrate processing apparatus suitable for the oxidizing process.

2. Description of the Prior Art

When a thermal oxidizing process is performed on a silicon (Si) wafer at a temperature lower than 1200° C. to form an oxide film (SiO₂ film) on the silicon wafer, members made of quartz (SiO₂) are usually used as structural members of a process furnace such as a reaction tube and a substrate holder.

In addition, according to a known technique (refer to Patent Documents 1 and 2), a silicon nitride (SiN) film is formed on a Si wafer at a temperature lower than 1200° C., and floating fine particles, which are generated as a result of forcibly cracking a SiN film adhered to a part such as a furnace made of quartz by increasing stress of the SiN film, are discharged to the outside of the furnace by purging. Furthermore, according to another known technique (refer to Patent Document 3), a SiN film adhered to a part such as a furnace made of quartz is forcibly cracked to relax stress of the SiN film, and then the SiN film is restored by re-covering the SiN film with a SiN film.

[Patent Document 1] International Publication No. WO 2005/029566 Pamphlet

[Patent Document 2] Japanese Unexamined Patent Application Publication No. 2000-306904

[Patent Document 3] Japanese Unexamined Patent Application Publication No. 2000-150496

In the case where a high-temperature thermal oxidizing process is performed on a Si wafer at a temperature equal to or higher than 1200° C. to form a SiO₂ film on the surface of the Si wafer, members made of thermally durable silicon carbide (SiC) are used as structural members of a process furnace such as a reaction tube and a substrate holder. In addition, since SiC members have good chemical-resistance, if SiC members are used, during a maintenance work, the problem that base materials are etched does not occur unlike the case of using quartz (SiO₂) members, and only SiO₂ films formed on the surfaces of the SiC members are etched so that the lifetime of the base materials can be increased.

However, oxide (SiO₂) films are also formed on the surfaces of the SiC members although the oxidation rate of SiC is low as compared with the oxidation rate of Si, for example, the oxidation rate of SiC is about 1/n (for example, ⅕) of the oxidation rate of Si, and as the thickness of the SiO₂ films increases, stress increases at the interfaces between the SiO₂ films and the surfaces of the SiC members to cause generation of cracks and particles which can be deposited on wafers. Such particles, being contaminants, become one of factors causing deterioration of device characteristics, and thus it is necessary to reduce such contaminants. Furthermore, this phenomenon occurs remarkably in an oxidizing process of a thick film having a thickness of 1 μm or greater, for example, in a process of forming an oxide film of a bonded wafer such as a silicon-on-insulator (SOI) wafer.

Furthermore, in the conventional art, if contaminants are generated, a maintenance work is performed as follows. That is, the inside temperature of a process furnace is decreased to room temperature; a SiC member (such as a substrate holder or a reaction tube) on which a SiO₂ film is formed is detached from the process furnace; and the SiO₂ film formed on the surface of the SiC member is removed by using a chemical such as hydrogen fluoride (HF) that etches SiO₂. After the SiO₂ film is removed, the SiC member is re-installed at the (heat) process furnace, and a wafer processing process is resumed in the following sequence: in-furnace temperature increasing, in-furnace temperature confirmation, and resuming of thermal oxidation. Therefore, maintenance time, that is, time (downtime) during which a wafer is not processed, is increased, and moreover, the possibility of member breakage increases due to additional manual operations necessary for detaching and installing the SiC member.

### SUMMARY OF THE INVENTION

An object of the present invention is to provide a semiconductor device manufacturing method and a substrate processing apparatus that are configured to reduce contaminants generating due to striping of an oxide film formed on a member made of silicon carbide.

According to an aspect of the present invention, there is provided a semiconductor device manufacturing method including: loading a substrate into a reaction tube made of silicon carbide; performing a process of forming an oxide film on a surface of the substrate by supplying an oxidizing gas to an inside of the reaction tube and causing thermal oxidation; unloading the processed substrate from the inside of the reaction tube; and in a state where the processed substrate is unloaded from the inside of the reaction tube, after increasing an inside temperature of the reaction tube until temperature of an oxide film formed on an inner wall surface of the reaction tube through the thermal oxidation is increased to at least a temperature corresponding to a strain point of the oxide film, decreasing the inside temperature of the reaction tube to below a temperature at which the processed substrate is unloaded from the inside of the reaction tube.

According to another aspect of the present invention, there is provided a semiconductor device manufacturing method including: loading a substrate into a reaction tube made of silicon carbide; performing a process of forming an oxide film on a surface of the substrate by supplying an oxidizing gas to an inside of the reaction tube and causing thermal oxidation; unloading the processed substrate from the inside of the reaction tube; and in a state where the processed substrate is unloaded from the inside of the reaction tube, after increasing an inside temperature of the reaction tube to at least 1100° C., decreasing the inside temperature of the reaction tube to below a temperature at which the processed substrate is unloaded from the inside of the reaction tube.

According to another aspect of the present invention, there is provided a substrate processing apparatus including: a reaction tube made of silicon carbide and configured to process a substrate; a heater configured to heat an inside of the reaction tube; an oxidizing gas supply system configured to supply an oxidizing gas to the inside of the reaction tube; an exhaust system configured to exhaust the inside of the reaction tube; and a controller configured to control the heater and the oxidizing gas supply system so as to: perform a process of forming an oxide film on a surface of the substrate by supplying an oxidizing gas to the inside of the reaction tube and causing thermal oxidation; and in a state where the processed substrate is unloaded from the inside of the reaction tube, increase an inside temperature of the reaction tube until temperature of an oxide film formed on an inner wall surface of the reaction tube through the thermal oxidation is increased to at least a temperature corresponding to a strain point of the oxide film, and then, decrease the inside temperature of the reaction tube to below a temperature at which the processed substrate is unloaded from the inside of the reaction tube.

### BRIEF DESCRIPTION OF THE DRAWINGS

FIG. 1 is a schematic perspective view illustrating a heat treatment apparatus according to an embodiment of the present invention.

FIG. 2 is a sectional view illustrating a reaction furnace used in the heat treatment apparatus according to an embodiment of the present invention.

FIG. 3 is a schematic vertical sectional view for explaining operations of members around the reaction furnace according to a first illustrative process sequence example relevant to an embodiment of the present invention, in which section (a) illustrates a state before a boat in which processed wafers are supported is taken out from the reaction furnace, section (b) illustrates a state where the boat in which processed wafers are supported is taken out from the reaction furnace and a furnace port of the reaction furnace is sealed by a shutter, and section (c) illustrates a state where the boat which is empty is re-loaded into the reaction furnace and the furnace port of the reaction furnace is sealed by a seal cap.

FIG. 4 is a time chart for explaining the first illustrative process sequence example of the embodiment of the present invention, in which section (a) illustrates a temperature control pattern of the inside of the reaction furnace, section (b) illustrates an O₂ gas supply control pattern, section (c) illustrates a N₂ gas supply control pattern, and section (d) illustrates processes in relation with the respective control patterns.

FIG. 5 is a schematic vertical sectional view for explaining operations of members around the reaction furnace according to a second illustrative process sequence example relevant to an embodiment of the present invention, in which section (a) illustrates a state before the boat in which processed wafers are supported is taken out from the reaction furnace, and section (b) illustrates a state where the boat in which processed wafers are supported is taken out from the reaction furnace and the furnace port of the reaction furnace is sealed by the shutter.

FIG. 6 is a time chart for explaining the second illustrative process sequence example of the embodiment of the present invention, in which section (a) illustrates a temperature control pattern of the inside of the reaction furnace, section (b) illustrates an O₂ gas supply control pattern, section (c) illustrates a N₂ gas supply control pattern, and section (d) illustrates processes in relation with the respective control patterns.

FIG. 7 is a graph illustrating accumulated film thickness and contaminant generation amount according to an embodiment of the present invention.

### DETAILED DESCRIPTION OF THE PREFERRED EMBODIMENTS

Embodiments of the present invention will be described hereinafter with reference to the attached drawings.

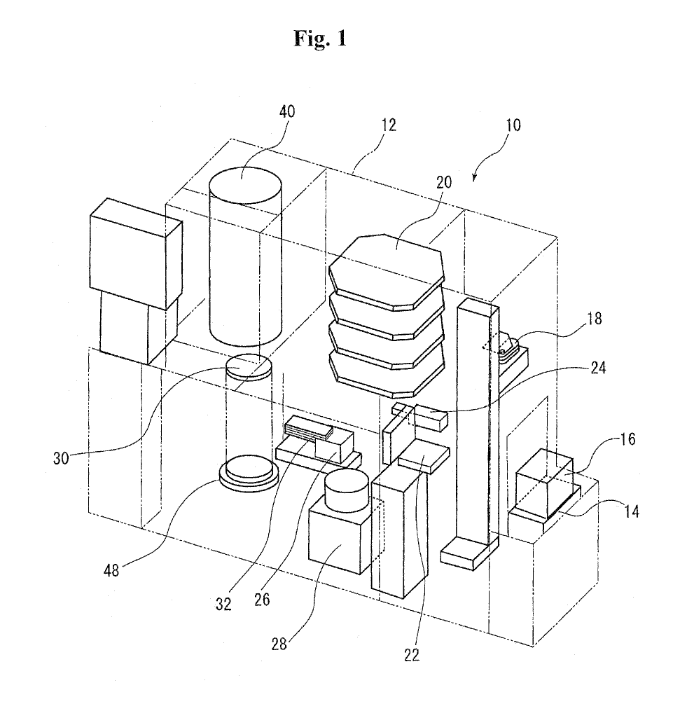

FIG. 1 illustrates a heat treatment apparatus 10 as an example of a substrate processing apparatus according to an embodiment of the present invention. The heat treatment apparatus 10 is a batch type vertical heat treatment apparatus and includes a housing 12 at which main parts are disposed. A pod stage 14 is connected to the front side of the housing 12, and a pod 16 is carried to the pod stage 14. In the pod 16, for example, twenty five wafers are accommodated as substrates to be processed, and the pod 16 is set on the pod stage 14 in a state where a cover (not shown) of the pod 16 is closed.

At a front-side position of the inside of the housing 12 facing the pod stage 14, a pod carrying device 18 is disposed. In addition, near the pod carrying device 18, a pod shelf 20, a pod opener 22, and a substrate number detector 24 are disposed. The pod shelf 20 is disposed above the pod opener 22, and the substrate number detector 24 is disposed close to the pod opener 22. The pod carrying device 18 is configured to carry the pod 16 among the pod stage 14, the pod shelf 20, and the pod opener 22. The pod opener 22 is used to open the cover of the pod 16, and after the cover of the pod 16 is opened, the number of wafers inside the pod 16 is detected by the substrate number detector 24.

In addition, at the inside of the housing 12, a substrate transfer machine 26, a notch aligner 28, and a boat (substrate holder) 30 are disposed. The substrate transfer machine 26 includes an arm (tweezers) 32 capable of picking up, for example, five wafers, and the substrate transfer machine 26 is configured to carry wafers among a pod 16 disposed at the pod opener 22, the notch aligner 28, and the boat 30 by operating the arm 32. The notch aligner 28 is configured to detect a notch or orientation flat formed on a wafer so as to align the notch or orientation flat with a predetermined position.

Furthermore, at the upper rear side of the inside of the housing 12, a reaction furnace 40 is disposed. At the inside of the reaction furnace 40, the boat 30 in which a plurality of wafers are charged is loaded, and heat treatment is performed.

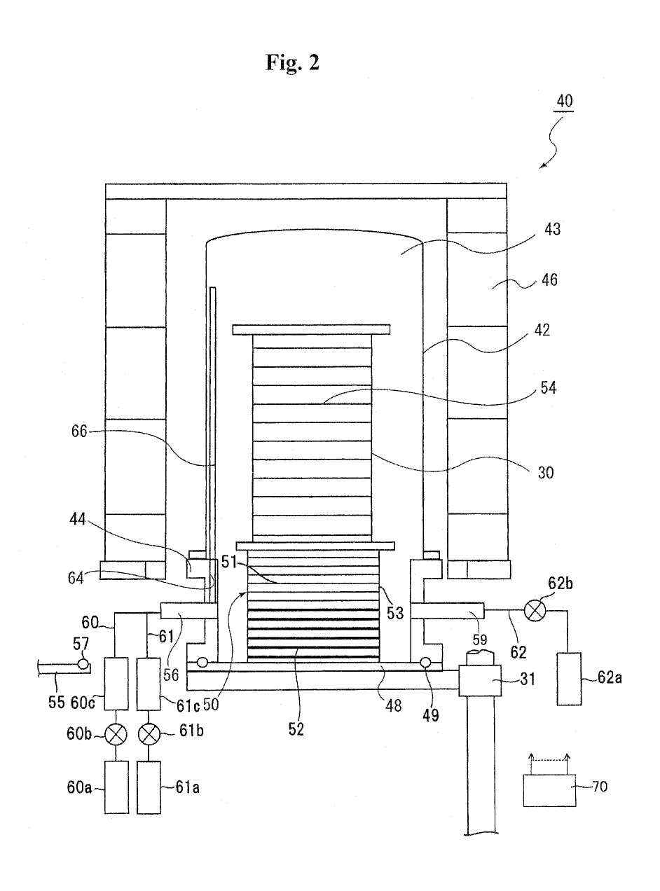

FIG. 2 illustrates an example of the reaction furnace 40. The reaction furnace 40 includes a reaction tube 42 made of silicon carbide (SiC). The reaction tube 42 has a cylindrical shape with a closed top side and an opened bottom side, and the opened bottom side has a flange shape. At the lower side of the reaction tube 42, an adapter 44 made of quartz is disposed to support the reaction tube 42. The adapter 44 has a cylindrical shape with opened top and bottom sides, and the opened top and bottom sides of the adapter 44 have a flange shape. The top surface of the top-side flange of the adapter 44 is in contact with the bottom surface of the bottom-side flange of the reaction tube 42. The reaction tube 42 and the adapter 44 constitute a reaction vessel 43. In addition, a heater 46, being a heating source (heating unit), is disposed around a part of the reaction vessel 43 including the reaction tube 42 but not including the adapter 44.

The lower side of the reaction vessel 43 constituted by the reaction tube 42 and the adapter 44 is opened so as to insert the boat 30 (substrate holder) made of SiC therethrough. The opened side (furnace port) can be air-tightly closed by bringing a seal cap (first cover body) 48 into contact with the bottom surface of the bottom-side flange of the adapter 44 with an O-ring 49 being disposed therebetween. The seal cap 48 is supported by a boat elevator 31 which is an elevating mechanism (elevating unit). The seal cap 48 is installed to support the boat 30 and be vertically moved together with the boat 30 by the boat elevator 31. Between the seal cap 48 and the boat 30, an insulating member 50 is installed. The insulating member 50 includes a plurality of insulating plates 51 made of SiC, a plurality of insulating plates 52 made of quartz and disposed under the insulating plates 51, and an insulating plate holder 53 made of SiC and configured to support the insulating plates 51 and 52. The boat 30 supports a plurality of wafers 54, for example, twenty five to one hundred wafers in a state where the wafers 54 are approximately horizontally positioned and are spaced in multiple stages, and the boat 30 is charged into the reaction tube 42. Furthermore, a shutter 55 is installed at the reaction furnace 40 as a second cover body configured to seal the opened bottom side of the reaction vessel 43 when the boat 30 is taken out from the inside of the reaction vessel 43. The shutter 55 is configured to seal the opened bottom side of the reaction vessel 43 air-tightly by making contact with the bottom surface of the bottom-side flange of the adapter 44 in a state where an O-ring 57 is disposed therebetween.

For performing a high-temperature process at a temperature of 1200° C. or higher, the reaction tube 42 is made of silicon carbide (SiC). If the SiC reaction tube 42 extends to the furnace port and the furnace port is sealed by the seal cap 48 with an O-ring being disposed therebetween, the sealed part is heated to a high temperature by heat transferred through the SiC reaction tube 42, and thus it is apprehended that the O-ring (sealing material) may fuse. If the sealed part of the SiC reaction tube 42 is cooled to prevent fusing of the O-ring, the reaction tube 42 may be broken due to non-uniform thermal expansion caused by temperature difference. However, if the SiC reaction tube 42 constitutes a heating region of the reaction vessel 43 that is heated by the heater 46 and the adapter 44 made of quartz constitutes a non-heating region of the reaction vessel 43 that is not heated by the heater 46, since heat transfer from the SiC reaction tube 42 is reduced, the furnace port can be sealed without the possibilities of fusing of the O-ring and breakage of the SiC reaction tube 42. Furthermore, if the interface between the SiC reaction tube 42 and the quartz adapter 44 is properly sealed in terms of surface accuracy, since the SiC reaction tube 42 is disposed in a heating region of the heater 46, the SiC reaction tube 42 can be thermally expanded without a temperature difference. Therefore, the bottom-side flange of the SiC reaction tube 42 can be kept flat and thus not spaced apart from the adapter 44, and owing to this, sealing can be ensured only by placing the SiC reaction tube 42 on the quartz adapter 44.

At the adapter 44, a gas supply port 56 and a gas exhaust port 59 are formed as one piece with the adapter 44. Gas introduction pipes 60 and 61 are connected to the gas supply port 56, and an exhaust pipe 62 is connected to the gas exhaust port 59. At the gas introduction pipe 60, an oxidizing gas source 60a, a valve 60b, a mass flow controller 60c being a flowrate controller are installed sequentially from the upstream side of the gas introduction pipe 60.

At the gas introduction pipe 61, an inert gas source 61a, a valve 61b, a mass flow controller 61c being a flowrate controller are installed sequentially from the upstream side of the gas introduction pipe 61. The exhaust pipe 62 is connected to an exhaust device 62a, and a valve 62b is installed at the exhaust pipe 62. An oxidizing gas supply system is constituted mainly by the gas introduction pipe 60, the oxidizing gas source 60a, the valve 60b, and the mass flow controller 60c. In addition, an inert gas supply system is constituted mainly by the gas introduction pipe 61, the inert gas source 61a, the valve 61b, and the mass flow controller 61c. In addition, an exhaust system is constituted mainly by the exhaust pipe 62, the exhaust device 62a, and the valve 62b.

The inner wall of the adapter 44 is located (protruded) more inwardly than the inner wall of the reaction tube 42, and at a sidewall part (thick part) of the adapter 44, a gas introduction passage 64 that communicates with the gas supply port 56 is vertically formed. At the upper side of the gas introduction passage 64, a nozzle installation hole is installed in a manner such that the nozzle installation hole is opened upwardly. At the inside of the reaction tube 42, the nozzle installation hole is formed in the top surface of the top-side flange of the adapter 44 and communicates with the gas supply port 56 and the gas introduction passage 64. A nozzle 66 made of SiC is inserted in and fixed to the nozzle installation hole. That is, at the inside of the reaction tube 42, the nozzle 66 is connected to and supported on the top surface of the part of the adapter 44 that is protruded more inwardly than the inner wall of the reaction tube 42. This structure prevents thermal deformation and breakage of the nozzle connection part. Furthermore, the nozzle 66 and the adapter 44 can be assembled and disassembled more easily. Oxidizing gas (process gas) and inert gas, which are introduced into the gas supply port 56 from the gas introduction pipes 60 and 61, are supplied to the inside of the reaction tube 42 through the gas introduction passage 64 and the nozzle 66, which are installed at the sidewall part of the adapter 44.

In addition, the nozzle 66 is configured to extend along the inner wall of the reaction tube 42 to a position higher than the top side of a substrate arrangement region, that is, the top side of the boat 30.

A controller 70 is configured to control operations of parts of the heat treatment apparatus 10 such as the oxidizing gas supply system, the inert gas supply system, the exhaust system, the elevating mechanism, and the heating source.

Next, an explanation will be given on a method of performing a wafer oxidizing process by using the above-described heat treatment apparatus 10 as one of semiconductor device manufacturing processes.

In the following explanation, each part of the heat treatment apparatus 10 is controlled by the controller 70.

First, when a pod 16 in which a plurality of wafers 54 are accommodated is set on the pod stage 14, the pod carrying device 18 carries the pod 16 from the pod stage 14 to the pod shelf 20 to stock the pod 16 on the pod shelf 20. Next, the pod carrying device 18 carries the pod 16 from the pod shelf 20 and sets the pod 16 on the pod opener 22, the pod opener 22 opens a cover of the pod 16, and the substrate number detector 24 detects the number of the wafers 54 accommodated in the pod 16.

Next, the substrate transfer machine 26 picks up a wafer 54 from the pod 16 disposed on the pod opener 22 and transfers the wafer 54 to the notch aligner 28. The notch aligner 28 detects a notch of the wafer 54 while rotating the wafer 54, so as to align notches of a plurality of wafers 54 to the same position based on detected information. Next, the substrate transfer machine 26 takes out the wafer from the notch aligner 28 and transfers the wafer 54 to the boat 30.

In this way, if a batch of wafers 54 is transferred to the boat 30, the shutter 55 is moved to open the furnace port of the reaction furnace 40, and the boat elevator 31 loads the boat 30 charged with the wafers 54 into the reaction furnace 40 (the reaction vessel 43) that is set to, for example, about 600° C. Then, the inside of the reaction furnace 40 is hermitically sealed by the seal cap 48. Thereafter, the inside of the reaction furnace 40 is heated to a process temperature of, for example, 1200° C. and is stabilized at the process temperature. After the inside temperature of the reaction furnace 40 is stabilized, the valve 60b is opened to introduce oxidizing gas into the reaction furnace 40. Oxidizing gas is introduced from the oxidizing gas source 60a into the reaction tube 42 through the valve 60b and the mass flow controller 60c of the gas introduction pipe 60, the gas supply port 56, the gas introduction passage 64, and the nozzle 66. The oxidizing gas introduced into the reaction tube 42 is exhausted by the exhaust device 62a through the gas exhaust port 59, the exhaust pipe 62, and the valve 62b. While oxidizing gas is introduced into the reaction tube 42 of which the inside temperature is kept at the process temperature, the wafers 54 are thermally oxidized, and thus oxide films (SiO₂ films) are formed on the surfaces of the wafers 54. At the same time, SiO₂ films are also formed on the surfaces of SiC members disposed inside the reaction furnace 40. For example, oxygen-containing gas such as oxygen (O₂) or vapor (H₂O) may be used as oxidizing gas. Meanwhile, at the same with the introduction of oxidizing gas, the valve 61b can be opened to introduce inert gas such as N₂ gas or Ar gas into the reaction furnace 40 for dilute the oxidizing gas with the inert gas.

After the wafers 54 are thermally processed (thermal oxidizing process), the valve 61b is opened to purge the inside of the reaction furnace 40 by supplying inert gas through the inert gas supply system while exhausting the inert gas through the exhaust system. Thereafter, the inside temperature of the reaction furnace 40 is decreased to, for example, about 600° C., and then the boat 30 in which the thermally-processed wafers 45 are supported is unloaded from the inside of the reaction furnace 40 and the furnace port of the reaction furnace 40 is sealed by using the shutter 55. Then, the boat 30 is placed at a predetermined standby position until the processed wafers 54 supported in the boat 30 are cooled. If the processed wafers 54 of the boat 30 is cooled to a predetermined temperature, the substrate transfer machine 26 picks up the processed wafers 54 from the boat 30 and carries the processed wafers 54 into an empty pod 16 set on the pod opener 22. Next, the pod 16 in which the processed wafers 54 are accommodated is carried to the pod shelf 20 or the pod stage 14 by the pod carrying device 18.

While the pod 16 in which the processed wafers 54 are accommodated is carried, it starts to increase and decrease the inside temperature of the reaction furnace 40. That is, after the processed wafers 54 are taken out from the boat 30, the furnace port of the reaction furnace 40 is opened by moving the shutter 55. Then, the empty boat 30 in which no wafer is charged is loaded into the reaction furnace 40, and the furnace port of the reaction furnace 40 is sealed by the seal cap 48. In this state, the inside temperature of the reaction furnace 40 is increased to at least about 1100° C. which is a strain point of SiO₂ formed on the surface of a SiC member disposed inside the reaction furnace 40, and then the inside temperature of the reaction furnace 40 is decreased (owing to this temperature decreasing operation, thermal stress caused by a temperature difference before and after the temperature decreasing operation is added to a SiO₂ film formed on the surface of the SiC member, and a decrease target temperature for increasing the film stress of the SiO₂ film higher than acritical value is determined by using equations described later). For this, the inside temperature of the reaction furnace 40 can be decreased by natural air cooling; however, preferably, the inside temperature of the reaction furnace 40 is decreased by forced cooling to increase thermal stress much more. In this case, for example, the temperature decreasing rate may be higher than a temperature decreasing rate of natural air cooling, about 3° C./min, but equal to or lower than about 20° C./min, preferably, equal to or lower than about 10° C./min. For the case where the inside temperature of the reaction furnace 40 is decreased by force cooling, it is preferable that a forced cooling mechanism (quick cooling mechanism) be installed at the heater 46. In the heater 46 of the current embodiment, a forced cooling mechanism is built so that the inside of the reaction furnace 40 can be forcibly (rapidly) cooled. In addition, the inside temperature of the reaction furnace 40 may be decreased to room temperature.

Thermal stress is added to the interface between the SiO₂ film and the SiC member owing to a temperature difference before and after the temperature decreasing, and as the film stress of the SiO₂ film exceeds a critical value, the SiO₂ formed on the SiC member inside the reaction furnace 40 is forcibly cracked and the film stress of the SiO₂ film is relaxed. Owing to this film stress relaxation of the SiO₂ film, although the thickness of the SiO₂ film (oxide film) on the SiC member is increased in the next batch process, the film stress of the SiO₂ film does not exceed a critical value during the process, and thus generation of contaminants can be suppressed. That is, in an oxidizing process, generation of contaminants caused by an increase of SiO₂ film thickness on the SiC member can be delayed. In other words, a critical film thickness, at which a SiO₂ film formed on the SiC member is cracked to generate contaminants, can be increased. Therefore, maintenance cycle time can be increased, and an increase of downtime can be prevented. In addition, since manual operations are reduced, the risk of member breakage can be reduced.

Since the inside temperature of the reaction furnace 40 is decreased after increasing the inside temperature of the reaction furnace 40 to the strain point of SiO₂, thermal stress on an SiO₂ film can be maximized, and the film stress of the SiO₂ film can be maximally relaxed, thereby preventing generation of contaminants more effectively. On the other hand, if the inside temperature of the reaction furnace 40 is not increased to the strain point of SiO₂, the film stress of the SiO₂ film is not sufficiently relaxed, and thus generation of contaminants cannot be sufficiently prevented.

SiO₂ is viscous at a high temperature. However, if SiO₂ is slowly cooled, SiO₂ becomes non-flowable at a certain temperature or lower. This temperature at which SiO₂ becomes non-flowable is a strain point of SiO₂, and if a force equal to or greater than a predetermined value is added to SiO₂ at a temperature equal to or lower than the strain point, cracks are generated at SiO₂.

That is, the inside temperature of the reaction furnace 40 is increased to at least a temperature corresponding to the strain point of SiO₂, and is then decreased so as to apply a thermal stress to a SiO₂ film formed on a SiC member and cause cracking of the SiO₂ film. In this case, it is rare that a crack develops to the SiC member, and thus, only the SiO₂ film is split due to a crack generated at the SiO₂ film weaker than the SiC member. It is considered that a crack generates in the SiO₂ film at a position close to the interface between the SiO₂ film and the SiC member and develops to the surface of the SiO₂ film.

Until the relaxation of the thermal stress of the SiO₂ film formed on the SiC member of the inside of the reaction furnace 40 is completed after the furnace port of the reaction furnace 40 is sealed by the seal cap 48, the valve 61b is opened to perform a gas purge process on the inside of the reaction furnace 40 by supplying inert gas such as Ar gas or N₂ gas to the inside of the reaction furnace 40 from the purge gas supply system at a high flowrate while exhausting the inside of the reaction furnace 40 by using the exhaust system. Owing to this, fine SiO₂ particles generating due to cracking of the SiO₂ film formed on the SiC member of the inside of the reaction furnace 40 can be discharged to the outside of the reaction furnace 40 through the exhaust system. At this time, the supply flowrate of inert gas is, for example, 10 slm to 20 slm. In addition, the inside pressure of the reaction furnace 40 is kept at atmospheric pressure.

In the case where the inside temperature of the reaction furnace 40 is reduced to room temperature, it takes time for increasing the inside temperature of the reaction furnace 40 again to about 600° C. for the next boat loading operation. Therefore, when throughput is considered, the inside temperature of the reaction furnace 40 may be reduced to a temperature higher than room temperature, for example, about 200° C.

In addition, when the inside temperature of the reaction furnace 40 is increased and decreased, the furnace port of the reaction furnace 40 can be sealed by the shutter 55. However, since the thermal durability of the shutter 55 is generally inferior to that of the seal cap 48, the shutter 55 may be thermally damaged by heat of the inside of the reaction furnace 40. On the other hand, if the empty boat 30 is loaded into the reaction furnace 40 to seal the furnace port of the reaction furnace 40 with the seal cap 48, since parts such as the insulating member 50 are installed above the seal cap 48, thermal influence of the inside of the reaction furnace 40 can be suppressed, and thus the seal cap 48 cannot be thermally damaged. In the case where the shutter 55 is made to have the same thermal durability as that of the seal cap 48, when the inside temperature of the reaction furnace 40 is increased and decreased, the furnace port can be sealed by using the shutter 55 as described later instead of loading the empty boat 30 into the reaction furnace 40.

In addition, the film stress relaxation operation may be performed on the SiO₂ film formed on the surface of the SiC member once for each batch or several batches. In any case, the film stress relaxation operation is performed before the thickness of the SiO₂ film formed on the surface of the SiC member is increased to a critical film thickness at which a crack starts to generate. The critical film thickness of the SiO₂ film formed on the surface of the SiC member at which cracking of the SiO₂ film starts may be several micrometers (μm).

After the increasing and decreasing of the inside temperature of the reaction furnace 40, the inside temperature of the reaction furnace 40 is increased to about 600° C. Thereafter, the empty boat 30 is unloaded from the inside of the reaction furnace 40, and the furnace port of the reaction furnace 40 is sealed by the shutter 55. Then, it starts to process the next batch. That is, the next wafers 54 to be processed are transferred to the boat 30. Alternatively, the procedure to the transfer of the next-batch wafers 54 into the boat 30 may be performed during the increasing and decreasing of the inside temperature of the reaction furnace 40.

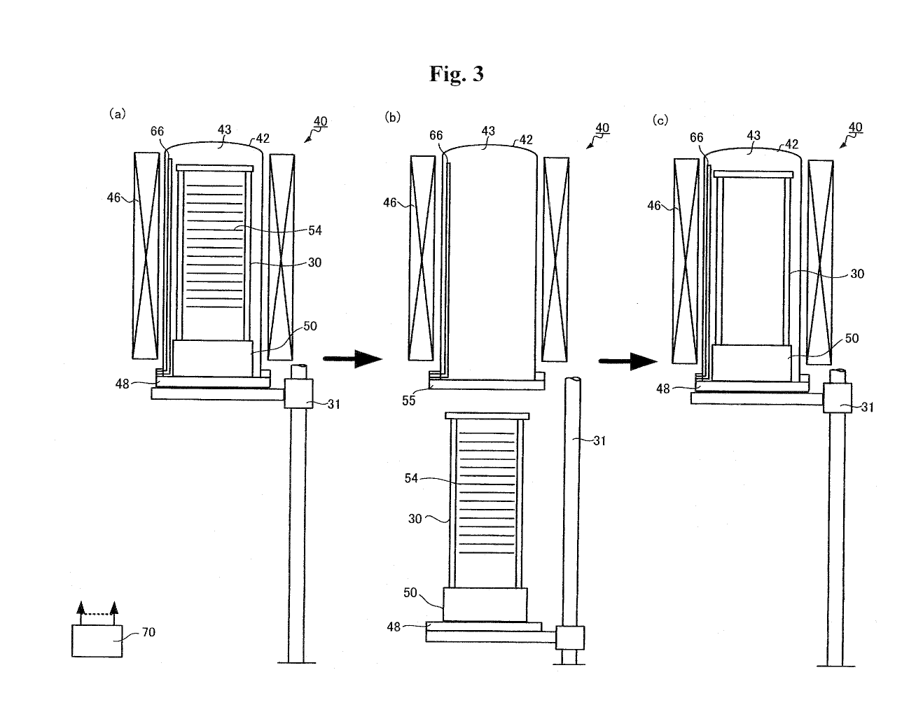

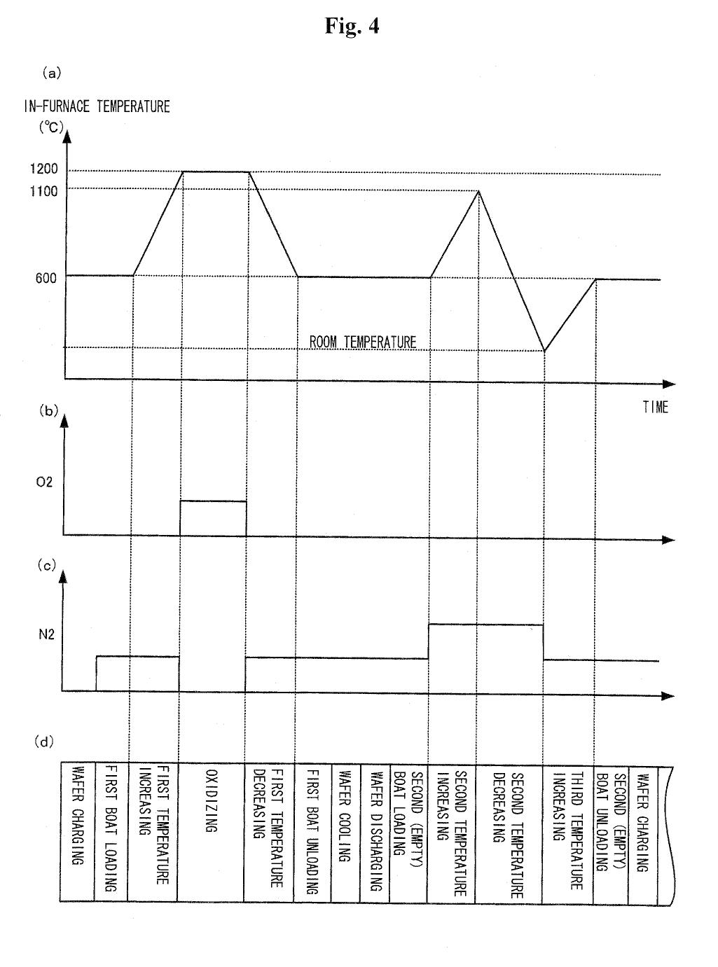

Next, a first illustrative process sequence example relevant to an embodiment will be described in detail with reference to FIG. 3 and FIG. 4.

FIG. 3 is a schematic vertical sectional view for explaining operations of members around the reaction furnace according to the first illustrative process sequence example relevant to an embodiment of the present invention

Section (a) of FIG. 3 illustrates a state before the boat 30 in which processed wafers 54 are supported is taken out from the reaction furnace 40, section (b) of FIG. 3 illustrates a state where the boat 30 in which the processed wafers 54 are supported is taken out from the reaction furnace 40 and the furnace port of the reaction furnace 40 is sealed by the shutter 55, and section (c) of FIG. 3 illustrates a state where the boat 30 which is empted is re-loaded into the reaction furnace 40 and the furnace port of the reaction furnace 40 is sealed by the seal cap 48.

FIG. 4 is a time chart for explaining the first illustrative process sequence example of the embodiment of the present invention, in which section (d) illustrates a flow of processes according to the process sequence, sections (a), (b), and (c) illustrate a temperature control pattern of the inside of the reaction furnace 40, an O₂ gas supply control pattern, and a N₂ gas supply control pattern, respectively. These processes are controlled by the controller 70.

First, in a state where the furnace port of the reaction furnace 40 is sealed by the shutter 55, a plurality of wafers 54 are charged into the boat 30 in a manner such that the wafers 54 are approximately horizontally positioned and are spaced in multiple stages (a wafer charging process). Next, the furnace port of the reaction furnace 40 is opened by moving the shutter 55; and while controlling the heater 46, the boat 30 in which the wafers 54 are charged is loaded into the reaction tube 42 of which the temperature is set to 600° C. as shown in section (a) of FIG. 4, so that the boat 30 charged with the wafers 54 can be accommodated in the reaction tube 42 as shown in section (a) of FIG. 3. At this time, as shown in section (c) of FIG. 4, inert gas such as N₂ gas is supplied to the inside of the reaction tube 42 through the nozzle 66 (a first boat loading process). Thereafter, while supplying N₂ gas to the inside of the reaction tube 42, the heater 46 is controlled as shown in section (a) of FIG. 4 so as to increase the inside temperature of the reaction furnace 40 to a process temperature of about 1200° C. (a first temperature increasing process). Then, while maintaining the inside temperature of the reaction furnace 40 at about 1200° C., as shown in section (b) of FIG. 4, the wafers 54 are oxidized by supplying O₂ gas as oxidizing gas to the inside of the reaction tube 42 through the nozzle 66 (an oxidizing process). At this time, N₂ gas can also be supplied to the inside of the reaction tube 42 to dilute the O₂ gas. After the oxidizing process, as shown in section (c) of FIG. 4, N₂ gas is supplied to the inside of the reaction tube 42 through the nozzle 66, and the heater 46 is controlled to decrease the inside temperature of the reaction furnace 40 to about 600° C. as shown in section (a) of FIG. 4 (a first temperature decreasing process). Thereafter, while supplying N₂ gas to the inside of the reaction tube 42 as shown in section (c) of FIG. 4 and controlling the heater 46 to maintain the inside temperature of the reaction furnace 40 at about 600° C. as shown in section (a) of FIG. 4, the boat 30 in which the processed wafers 54 are supported is unloaded from the reaction tube 42 (a first boat unloading process), and the furnace port of the reaction furnace 40 is sealed by the shutter 55 as shown in section (b) of FIG. 3. Then, at that state, the processed wafers 54 are cooled (a wafer cooling process). After the wafer cooling process, the wafers 54 are discharged from the boat 30 (a wafer discharging process).

Next, the shutter 55 is moved to open the furnace port of the reaction furnace 40; and while supplying N₂ gas to the inside of the reaction tube 42 through the nozzle 66 as shown in section (c) of FIG. 4, the empty boat 30 is loaded into the reaction tube 42 of which the temperature is kept at about 600° C. as shown in section (a) of FIG. 4 (a second boat loading process), and the furnace port of the reaction furnace 40 is sealed by using the seal cap 48 as shown in section (c) of FIG. 3. Thereafter, while controlling the heater 46, as shown in section (a) of FIG. 4, the inside temperature of the reaction furnace 40 is first increased to about 1100° C. which is a strain point of SiO₂ formed on a SiC member of the inside of the reaction furnace 40 (a second temperature increasing process), and as shown in section (c) of FIG. 4, N₂ gas is supplied to the inside of the reaction tube 42 through the nozzle 66 at a high flowrate. Then, while supplying N₂ gas to the inside of the reaction tube 42 at a high flowrate, as shown in section (a) of FIG. 4, the heater 46 is controlled to decrease the inside temperature of the reaction furnace 40 from about 1100° C. to about room temperature (a second temperature decreasing process). During this period, N₂ gas is continuously supplied to the inside of the reaction tube 42 at a high flowrate. After that, while supplying N₂ gas to the inside of the reaction tube 42 through the nozzle 66 as shown in section (c) of FIG. 4, the heater 46 is controlled as shown in section (a) of FIG. 4 so as to increase the inside temperature of the reaction furnace 40 to about 600° C. (a third temperature increasing process), and while keeping the inside temperature of the reaction furnace 40 at about 600° C., the empty boat 30 is unloaded from the reaction furnace 40 (a second boat unloading process). Thereafter, the furnace port of the reaction furnace 40 is sealed by the shutter 55, and the next wafers 54 to be processed are charged into the boat 30 (a wafer charging process) for performing the next batch process.

That is, in a state where the empty boat 30 is loaded into the reaction furnace 40 and the furnace port of the reaction furnace 40 is sealed by the seal cap 48 as shown in section (c) of FIG. 3, the second temperature increasing process and the second temperature decreasing process are performed, and at that time, N₂ gas is supplied to the inside of the reaction tube 42 at a high flowrate to purge the inside of the reaction furnace 40 (in-furnace temperature increasing and decreasing purge). By this, the film stress of the SiO₂ film formed on the SiC member can be relaxed, and SiO₂ particles generated at that time can be discharged to the outside of the reaction furnace 40. Owing to this, in an oxidizing process, generation of contaminants caused by an increase of SiO₂ film thickness on the SiC member can be delayed. In other words, a critical film thickness, at which a SiO₂ film formed on the SiC member is cracked to generate contaminants, can be increased. Therefore, maintenance cycle time can be increased, and an increase of downtime can be prevented. In addition, since manual operations are reduced, the risk of member breakage can be reduced.

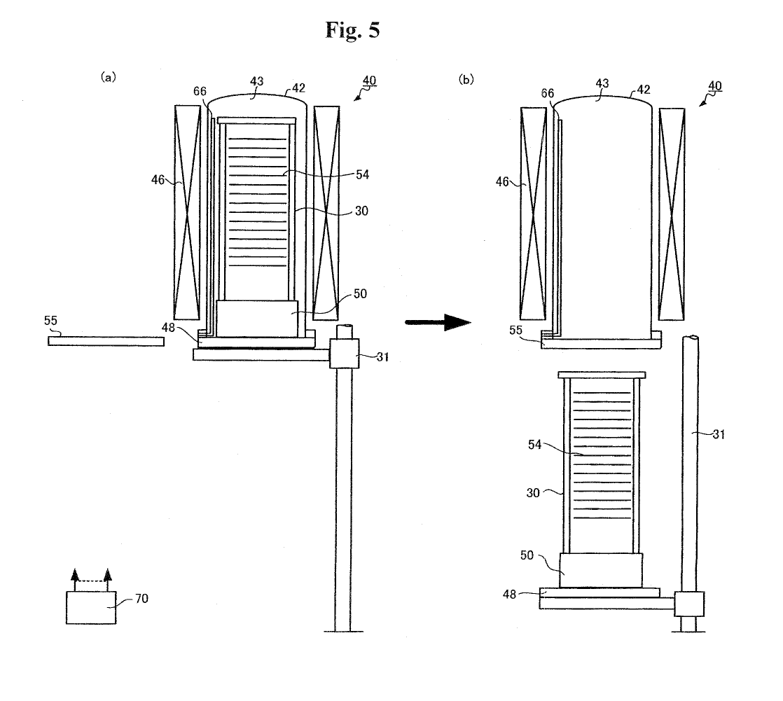

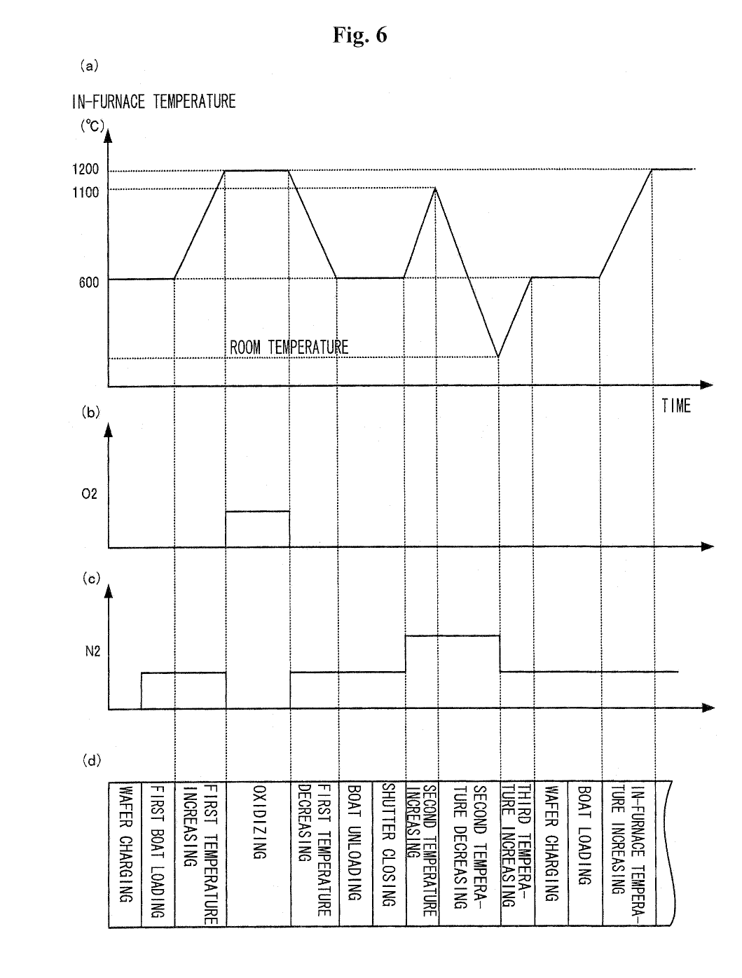

Next, a second illustrative process sequence example relevant to an embodiment will be described in detail with reference to FIG. 5 and FIG. 6.

FIG. 5 is a schematic vertical sectional view for explaining operations of members around the reaction furnace according to the second illustrative process sequence example relevant to an embodiment of the present invention

Section (a) of FIG. 5 illustrates a state before the boat 30 in which processed wafers 54 are supported is taken out from the reaction furnace 40, and section (b) of FIG. 5 illustrates a state where the boat 30 in which the processed wafers 54 are supported is taken out from the reaction furnace 40 and the furnace port of the reaction furnace 40 is sealed by the shutter 55.

FIG. 6 is a time chart for explaining the second illustrative process sequence example of the embodiment of the present invention, in which section (d) illustrates a flow of processes according to the process sequence, sections (a), (b), and (c) illustrate a temperature control pattern of the inside of the reaction furnace 40, an O₂ gas supply control pattern, and a N₂ gas supply control pattern, respectively. These processes are controlled by the controller 70.

In the second illustrative process sequence example relevant to an embodiment of the present invention, processes from a wafer charging process to about unloading process are equal to the processes from the wafer charging process to the first boat unloading process of the first illustrative process sequence. In the second illustrative process sequence example, processes next to the above-mentioned processes are different from those of the first illustrative process sequence example. That is, in the second illustrative process sequence example, from the state where the boat 30 is accommodated in the reaction tube 42 as shown in section (a) of FIG. 5, the boat 30 in which processed wafers 54 are supported is unloaded from the inside of the reaction tube 42 (a boat unloading process), and in the state where the boat 30 is unloaded, the furnace port of the reaction furnace 40 is sealed by the shutter 55 (a shutter closing process) as shown in section (b) of FIG. 5. During the processes, N₂ gas is continuously supplied to the inside of the reaction tube 42. Thereafter, while controlling the heater 46, as shown in section (a) of FIG. 6, the inside temperature of the reaction furnace 40 is first increased to about 1100° C. which is a strain point of SiO₂ formed on a SiC member of the inside of the reaction furnace 40 (a second temperature increasing process), and as shown in section (c) of FIG. 6, N₂ gas is supplied to the inside of the reaction tube 42 through the nozzle 66 at a high flowrate. Then, while supplying N₂ gas to the inside of the reaction tube 42 at a high flowrate, as shown in section (a) of FIG. 6, the heater 46 is controlled to decrease the inside temperature of the reaction furnace 40 from about 1100° C. to about room temperature (a second temperature decreasing process). During this process, N₂ gas is also continuously supplied to the inside of the reaction tube 42 at a high flowrate. After that, while supplying N₂ gas to the inside of the reaction tube 42 through the nozzle 66 as shown in section (c) of FIG. 6, the heater 46 is controlled as shown in section (a) of FIG. 6 so as to increase the inside temperature of the reaction furnace 40 to about 600° C. (a third temperature increasing process), and while keeping the inside temperature of the reaction furnace 40 at about 600° C., the next wafers 54 to be processed are charged into the boat 30 (a wafer charging process) for performing the next batch process.

That is, according to the second illustrative process sequence example relevant to an embodiment of the present invention, instead of loading the boat 30 which is empty into the reaction furnace 40, in a state where the boat 30 is unloaded as shown in section (b) of FIG. 5, the furnace port of the reaction furnace 40 is sealed by the shutter 55 to perform the second temperature increasing process and the second temperature decreasing process, and at that time, N₂ gas is supplied to the inside of the reaction tube 42 at a high flowrate to purge the inside of the reaction furnace 40 (in-furnace temperature increasing and decreasing purge).

In this way, the second illustrative process sequence example results in the same operational effects as the first illustrative process sequence example.

The second illustrative process sequence example is executable in the case where the shutter 55 have thermal durability equivalent to that of the seal cap 48.

[Experimental Example]

By using a heat treatment apparatus of an embodiment of the present invention, processes from a wafer charging process to a wafer discharging process were repeated a plurality of times according to the process sequence of FIG. 4 so as to repeat an oxidizing process (batch process) a plurality of times and measure the amount of generated contaminants; and in addition to that, in-furnace temperature increasing and decreasing purge was performed during processes from a second boat loading process to a second boat unloading process performed according to the process sequence of FIG. 4, so as to measure the amounts of generated contaminants before and after the in-furnace temperature increasing and decreasing purge.

The oxidizing process was performed under the conditions of in-furnace temperature: 1200° C. to 1300° C., in-furnace pressure: atmospheric pressure, O₂ gas flowrate: 10 slm to 20 slm, and oxidizing time: 100 hours or more.

The in-furnace temperature increasing and decreasing purge was performed under the conditions of in-furnace temperature: 600° C.→1100° C.→room temperature, in-furnace pressure: atmospheric pressure, N₂ gas flowrate: 10 slm to 20 slm, and purge time: 24 hours or more.

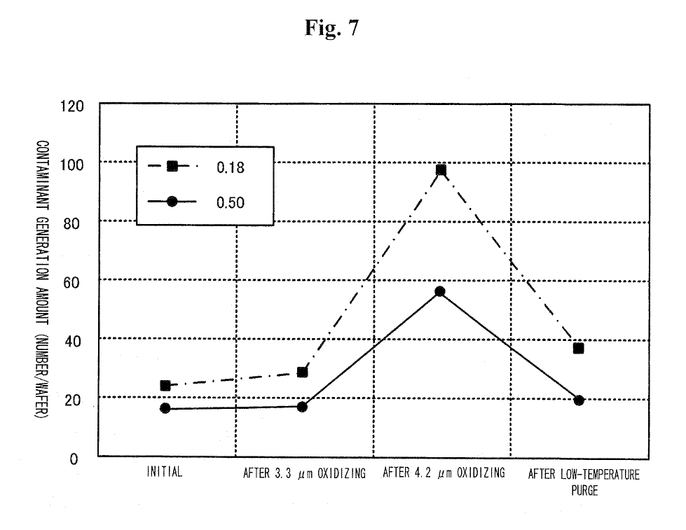

The results are shown in FIG. 7.

The sequence and results of the experiment will now be specifically mentioned as follows. That is, first, after the oxidizing process was initially performed, the amount of contaminants equal to or greater than 0.50 μm, and the amount of contaminants equal to or greater than 0.18 μm but smaller than 50 μm were measured. The number of contaminants equal to or greater than 0.50 μm was 17/wafer, and the number of contaminants equal to or greater than 0.18 μm but smaller than 50 μm was 25/wafer.

Next, when the accumulated thickness of a SiO₂ film formed on a wafer became 3.3 μm after the oxidizing process was repeated a plurality of times, the amounts of contaminants were measured according to the sizes of the contaminants. The number of contaminants equal to or greater than 0.50 μm was 18/wafer, and the number of contaminants equal to or greater than 0.18 μm but smaller than 50 μm was 30/wafer.

Next, when the accumulated thickness of the SiO₂ film formed on the wafer became 4.2 μm after the oxidizing process was further repeated, the amounts of contaminants were measured according to the sizes of the contaminants. The amounts of contaminants were steeply increased: the number of contaminants equal to or greater than 0.50 μm was 57/wafer, and the number of contaminants equal to or greater than 0.18 μm but smaller than 50 μm was 98/wafer.

Next, after performing the in-furnace temperature increasing and decreasing purge to relax stress of a SiO₂ film formed on a SiC member and then performing the oxidizing process, the amounts of contaminants were measured according to the sizes of the contaminants. The amounts of contaminants were steeply decreased: the number of contaminants equal to or greater than 0.50 μm was 20/wafer, and the number of contaminants equal to or greater than 0.18 μm but smaller than 50 μm was 38/wafer.

As shown in FIG. 7, until the accumulated thickness of a SiO₂ film formed on a wafer became 3.3 μm, the amounts of generated contaminants were low and stably maintained in all sizes of the contaminants; however, when the accumulated thickness became 4.2 μm, the amounts of generated contaminants were steeply increased in all sizes of the contaminants. However, after the in-furnace temperature increasing and decreasing purge was performed from the state, the amounts of generated contaminants were steeply decreased.

That is, in the case where the in-furnace temperature increasing and decreasing purge was not performed, while the accumulated thickness of a SiO₂ film formed on a wafer was increased from 3.3 μm to 4.2 μm, the thickness of a SiO₂ film formed on a SiC member was increased to a critical film thickness at which a crack was generated. However, in the case where the in-furnace temperature increasing and decreasing purge was performed, the critical film thickness could be increased, and thus the time period to a steep increase of contaminant generation could be extended.

The present invention can be applied to a case where the thickness of a SiO₂ film formed during a thermal oxidizing process for a batch does not exceed a critical value (ranging from 3.3 μm to 4.2 μm).

Furthermore, if a SiO₂ film formed on a wafer/batch to a thickness equal to or greater than 1 μm is referred to as a thick film and a SiO₂ film formed on a wafer/batch to a thickness equal to or smaller than 0.1 μm is referred to as a thin film, the present invention is more effective in the case of performing a thick film oxidizing process. That is, the present invention is particularly effective in the case of forming a SiO₂ film on a batch to a thickness equal to or greater than 1 μm.

Next, the relationship between film stress and critical value of crack generation will be described.

Film stress σ_{T} is a stress generated at the interface between a film (a SiO₂ film) and a base material (SiC member) and can be expressed by Equation 1 below.

$${σ}_{T} = {σ}_{int} + {σ}_{th} \\ {σ}_{th} = \frac{{E}_{f}}{1 - {v}_{f}} ( {α}_{s} - {α}_{f} ) \times Δ T \qquad [ Equation 1 ]$$

In Equation 1, σᵢₙₜ denotes film intrinsic stress that is determined by the kind of a film. σₜₕ denotes thermal stress, E denotes Young's modulus, ν denotes Poisson ratio, α denotes thermal expansion coefficient, ΔT denotes temperature difference, suffix f denotes a film, and s denotes a base material.

Energy U generated by film stress can be expressed according to Hooke's law as Equation 2 below.

$${σ}_{T} = {E}_{f} \cdot ɛ = E \cdot Δ l \\ ∴ Δ l = \frac{{σ}_{T}}{E} \\ U = F \times \frac{Δ l}{2} = {σ}_{T} \cdot {T}_{thick} \cdot \frac{{σ}_{T}}{2 {E}_{f}} = \frac{{σ}_{T}^{2}}{2 {E}_{f}} \cdot {T}_{thick} \\ ( F = {σ}_{T} \cdot {T}_{thick} ) \qquad [ Equation 2 ]$$

In Equation 2, F denotes transversal force, Δl denotes strain per unit length, and T_{thick} denotes film thickness. When energy U is equal to or greater than interfacial energy γ existing between a film and a base material as expressed by Equation 3 below, a crack may be generated at the interface between the film and the base material.

$$U = \frac{{σ}_{T}^{2}}{2 {E}_{f}} \cdot {T}_{thick} \geq γ \qquad [ Equation 3 ]$$

Since interfacial energy γ is determined by the materials of a film and a base material, a critical thickness T_{thick} at which a crack is generated can be calculated for a combination of all members.

In the above-described embodiments, a batch type heat treatment apparatus is explained, which processes a plurality of wafers at a time; however, the present invention is not limited thereto. For example, the present invention can be applied to a single wafer apparatus.

According to the present invention, contaminants generating due to striping of an oxide film formed on a member made of silicon carbide can be reduced.

(Supplementary Note)

The present invention also includes the following preferable embodiments.

(Supplementary Note 1)

According to a preferred embodiment of the present invention, there is provided a semiconductor device manufacturing method including: loading a substrate into a reaction tube made of silicon carbide; performing a process of forming an oxide film on a surface of the substrate by supplying an oxidizing gas to an inside of the reaction tube and causing thermal oxidation; unloading the processed substrate from the inside of the reaction tube; and in a state where the processed substrate is unloaded from the inside of the reaction tube, after increasing an inside temperature of the reaction tube until temperature of an oxide film formed on an inner wall surface of the reaction tube through the thermal oxidation is increased to at least a temperature corresponding to a strain point of the oxide film, decreasing the inside temperature of the reaction tube to below a temperature at which the processed substrate is unloaded from the inside of the reaction tube.

(Supplementary Note 2)

In the semiconductor device manufacturing method of Supplementary Note 1, during the decreasing of the inside temperature of the reaction tube, the inside temperature of the reaction tube may be decreased to a temperature equal to or higher than room temperature but equal to or lower than about 200° C.

(Supplementary Note 3)

In the semiconductor device manufacturing method of Supplementary Note 1, during the decreasing of the inside temperature of the reaction tube, the inside temperature of the reaction tube may be decreased to a temperature equal to or higher than room temperature but equal to or lower than about 200° C. after the inside temperature of the reaction tube may be increased to at least 1100° C.

(Supplementary Note 4)

In the semiconductor device manufacturing method of Supplementary Note 1, during the decreasing of the inside temperature of the reaction tube, thermal stress may be added to an interface between the reaction tube and the oxide film formed on the inner wall surface of the reaction tube, and the oxide film formed on the inner wall surface of the reaction tube may be forcibly cracked such that film stress of the oxide film may be relaxed.

(Supplementary Note 5)

In the semiconductor device manufacturing method of Supplementary Note 1, during the decreasing of the inside temperature of the reaction tube, the inside of the reaction tube may be purged by inert gas.

(Supplementary Note 6)

According to another preferred embodiment of the present invention, there is provided a semiconductor device manufacturing method including: loading a substrate into a reaction tube made of silicon carbide; performing a process of forming an oxide film on a surface of the substrate by supplying an oxidizing gas to an inside of the reaction tube and causing thermal oxidation; unloading the processed substrate from the inside of the reaction tube; and in a state where the processed substrate is unloaded from the inside of the reaction tube, after increasing an inside temperature of the reaction tube to at least 1100° C., decreasing the inside temperature of the reaction tube to below a temperature at which the processed substrate is unloaded from the inside of the reaction tube.

(Supplementary Note 7)

In the semiconductor device manufacturing method of Supplementary Note 6, during the decreasing of the inside temperature of the reaction tube, the inside temperature of the reaction tube may be decreased to a temperature equal to or higher than room temperature but equal to or lower than about 200° C.

(Supplementary Note 8)

In the semiconductor device manufacturing method of Supplementary Note 6, during the decreasing of the inside temperature of the reaction tube, the inside of the reaction tube may be purged by inert gas.

(Supplementary Note 9)

According to another preferred embodiment of the present invention, there is provided a substrate processing apparatus including: a reaction tube made of silicon carbide and configured to process a substrate; a heater configured to heat an inside of the reaction tube; an oxidizing gas supply system configured to supply an oxidizing gas to the inside of the reaction tube; an exhaust system configured to exhaust the inside of the reaction tube; and a controller configured to control the heater and the oxidizing gas supply system so as to: perform a process of forming an oxide film on a surface of the substrate by supplying an oxidizing gas to the inside of the reaction tube and causing thermal oxidation; and in a state where the processed substrate is unloaded from the inside of the reaction tube, increase an inside temperature of the reaction tube until temperature of an oxide film formed on an inner wall surface of the reaction tube through the thermal oxidation is increased to at least a temperature corresponding to a strain point of the oxide film, and then, decrease the inside temperature of the reaction tube to below a temperature at which the processed substrate is unloaded from the inside of the reaction tube.

(Supplementary Note 10)

The substrate processing apparatus of Supplementary Note 9 may further include an inert gas supply system configured to supply inert gas to the inside of the reaction tube, wherein the controller may be further configured to control the inert gas supply system so as to purge the inside of the reaction tube with inert gas when decreasing the inside temperature of the reaction tube.

What is claimed is:

1. A semiconductor device manufacturing method comprising:
loading a substrate into a reaction tube made of silicon carbide;
performing a process of forming an oxide film on a surface of the substrate by supplying an oxidizing gas to an inside of the reaction tube and causing thermal oxidation;
unloading the processed substrate from the inside of the reaction tube; and
in a state where the processed substrate is unloaded from the inside of the reaction tube, after increasing an inside temperature of the reaction tube until temperature of an oxide film formed on an inner wall surface of the reaction tube through the thermal oxidation is increased to at least a temperature corresponding to a strain point of the oxide film, decreasing the inside temperature of the reaction tube to below a temperature at which the processed substrate is unloaded from the inside of the reaction tube.

2. The semiconductor device manufacturing method of claim 1, wherein in the decreasing of the inside temperature of the reaction tube, the inside temperature of the reaction tube is decreased to a temperature equal to or higher than room temperature but equal to or lower than about 200° C.

3. The semiconductor device manufacturing method of claim 1, wherein in the decreasing of the inside temperature of the reaction tube, the inside temperature of the reaction tube is decreased to a temperature equal to or higher than room temperature but equal to or lower than about 200° C. after the inside temperature of the reaction tube is increased to at least 1100° C.

4. The semiconductor device manufacturing method of claim 1, wherein in the decreasing of the inside temperature of the reaction tube, thermal stress is added to an interface between the reaction tube and the oxide film formed on the inner wall surface of the reaction tube, and the oxide film formed on the inner wall surface of the reaction tube is forcibly cracked such that film stress of the oxide film is relaxed.

5. The semiconductor device manufacturing method of claim 1, wherein in the decreasing of the inside temperature of the reaction tube, the inside of the reaction tube is purged by inert gas.

6. A semiconductor device manufacturing method comprising:
loading a substrate into a reaction tube made of silicon carbide;
performing a process of forming an oxide film on a surface of the substrate by supplying an oxidizing gas to an inside of the reaction tube and causing thermal oxidation;
unloading the processed substrate from the inside of the reaction tube; and
in a state where the processed substrate is unloaded from the inside of the reaction tube, after increasing an inside temperature of the reaction tube to at least 1100° C., decreasing the inside temperature of the reaction tube to below a temperature at which the processed substrate is unloaded from the inside of the reaction tube.

7. The semiconductor device manufacturing method of claim 6, wherein in the decreasing of the inside temperature of the reaction tube, the inside temperature of the reaction tube is decreased to a temperature equal to or higher than room temperature but equal to or lower than about 200° C.

8. The semiconductor device manufacturing method of claim 6, wherein in the decreasing of the inside temperature of the reaction tube, the inside of the reaction tube is purged by inert gas.

9. A substrate processing apparatus comprising:
a reaction tube made of silicon carbide and configured to process a substrate;
a heater configured to heat an inside of the reaction tube;
an oxidizing gas supply system configured to supply an oxidizing gas to the inside of the reaction tube;
an exhaust system configured to exhaust the inside of the reaction tube; and
a controller configured to control the heater and the oxidizing gas supply system so as to:
perform a process of forming an oxide film on a surface of the substrate by supplying an oxidizing gas to the inside of the reaction tube and causing thermal oxidation; and
in a state where the processed substrate is unloaded from the inside of the reaction tube, increase an inside temperature of the reaction tube until temperature of an oxide film formed on an inner wall surface of the reaction tube through the thermal oxidation is increased to at least a temperature corresponding to a strain point of the oxide film, and then, decrease the inside temperature of the reaction tube to below a temperature at which the processed substrate is unloaded from the inside of the reaction tube.

10. The substrate processing apparatus of claim 9, further comprising an inert gas supply system configured to supply inert gas to the inside of the reaction tube,
wherein the controller is further configured to control the inert gas supply system so as to purge the inside of the reaction tube with inert gas when decreasing the inside temperature of the reaction tube.
